(19) United States
(12) Patent Application Publication
(10) Pub. No.: US 2003/0160320 A1
(43) Pub. Date: Aug. 28, 2003

(54) High heat dissipation micro-packaging body for semiconductor chip

(76) Inventors: Wen-Lo Shieh, Taipei (TW); Chia-Ming Yang, Taipei (TW); Shu-Fen Liang, Taipei (TW); Yen-Shu Hsieh, Taipei (TW); Shu-Min Chou, Taipei (TW); Chun-Lung Tseng, Taipei (TW)

Correspondence Address: Wen-Lo SHIEH, PO Box 82-244, Taipei, TW

(21) Appl. No.: 10/196,940

(22) Filed: Jul. 18, 2002

(30) Foreign Application Priority Data
Feb. 26, 2002 (TW) 091103722

(51) Int. Cl. H01L 23/495; H01L 23/34

(52) U.S. Cl. 257/712; 257/675; 257/706

(57) ABSTRACT

A high heat dissipation micro-packaging body for semiconductor chip is disclosed and the body comprises lead frame having an etched recessed platform for a chip seat, the surrounding area of the platform being groove having a plurality of supporting belt connected to the lead frame; a substrate having a plurality of pins, corresponding to the position of the groove, for connection with gold lines; a chip being bonded to the chip seat of the lead frame with bonding agent, the gold lines being mounted at the predetermined electrically connection pin positions of the substrate and a pin pad so as to function as output, and heat energy evolved in the course of operation of the chip is dissipated from the chip seat via the support belt to other regions of the lead frame for dissipation.

### BACKGROUND OF THE INVENTION

(a) Field of the Invention

The present invention relates to a heat dissipation micro-packaging body, and in particular, to a high heat dissipation device comprising a lead frame and a substrate, wherein the substrate is provided with a recess to place chip seat to hold chips.

(b) Description of the Prior Art

As shown in FIG. 1, there is shown a conventional packaging for semiconductor chip used on TEBGA or HQFP. The packaging body has a substrate 1′ bonded to a chip 2′ using a bonding agent 23′. Bonding technique is used to connect gold wire 22′ from the pin pad 21′ of the chip 2′ to the substrate 1′. Next a heat dissipation plate 3′ covers the chip 2′ and the gold line 22′. The surrounding of the dissipation plate 3′ is packaged with sealing gel 5′. As the outside of the chip 2′ needs the heat dissipation plate 3′, the objective of having a small size and thickness cannot be achieved.

Referring to FIG. 2, there is shown packaging body used in EBGA and TBGA. The structure consists of a substrate connected to a copper plate, and the copper plate is used as a heat dissipation source. The substrate 1′ and the copper plate 4′ are adhered together and a hole (not shown) is opened on the substrate 1′ such that the chip 2′ is positioned on the hole and adhered on the copper plate 4′. The gold line 22′ is connected to the pin pad 21′ of the chip 2′ and the substrate 1′ to output to the chip 2′. As the chip 2′ has to be located at the lower position of the packaging body, the implant of the solder 12 on the surface of the substrate 1′ has to take into consideration the size of the chip and the positioning region of the soldered line. As a result, the size of the entire packaging cannot be effectively reduced. Accordingly, it is an object of the present invention to provide a high dissipation packaging body for semiconductor chip which mitigates the above drawbacks.

### SUMMARY OF THE INVENTION

Accordingly, it is an object of the present invention to provide a high heat dissipation micro-packaging body for semiconductor chip, wherein the lead frame is used to hold chip, and copper alloy is used to function as heat dissipation fins, which can effectively reduce the entire volume of the packaging device, in particular, the thickness thereof.

Another object of the present invention is to provide a high heat dissipation micro-packaging body for semiconductor chip wherein the lead frame is used to replace copper plate or heat dissipation fins, which in turn, reduces the cost of production.

Yet another object of the present invention is to provide a high heat dissipation micro-packaging body for semiconductor chip wherein the substrate is fully use to fabricate packaging body with high number of pins.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIGS. 1 and 2 schematically show structure of conventional packaging body having heat dissipation fins.

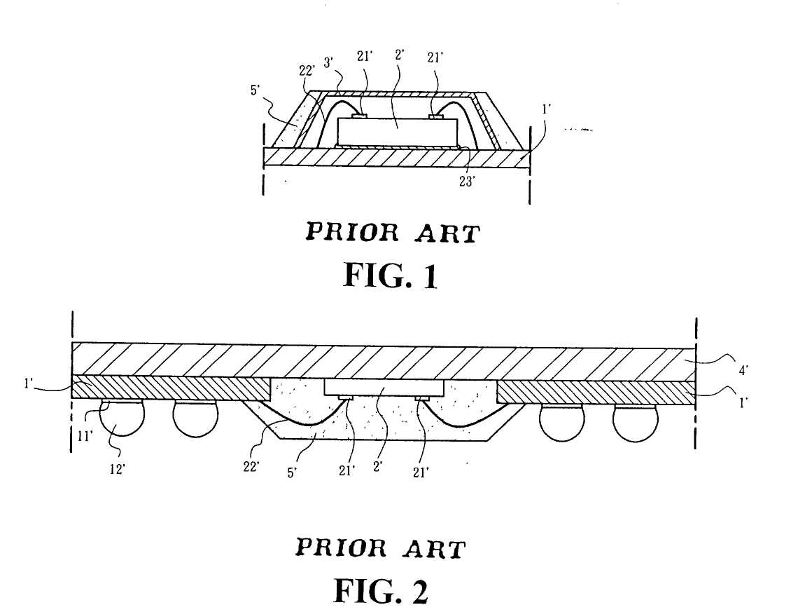

FIG. 3 shows lead frame structure in accordance with the present invention.

FIG. 4 schematically shows the structure of the packaging element in accordance with the present invention.

### DETAILED DESCRIPTION OF THE PRESENT INVENTION

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

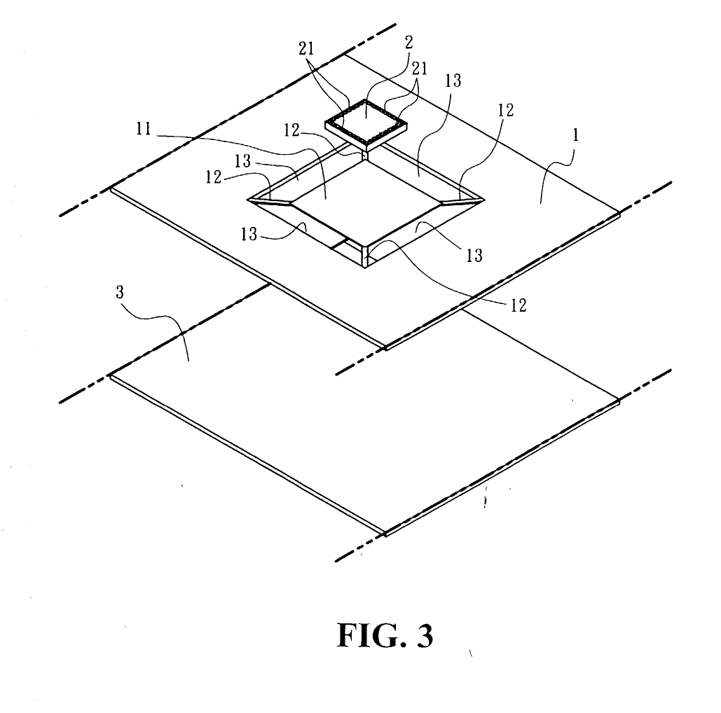

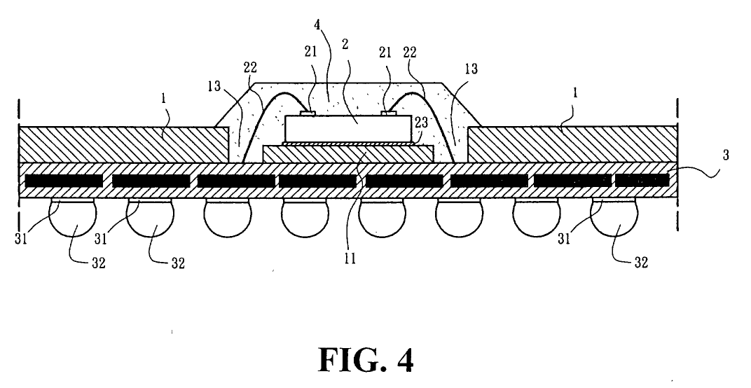

Referring to FIGS. 3 and 4, there is shown a high heat dissipation micro-packaging body for semiconductor chip comprising lead frame having an etched recessed platform for a chip seat, the surrounding area of the platform being groove having a plurality of supporting belt connected to the lead frame; a substrate having a plurality of pins, corresponding to the position of the groove, for connection with gold lines; a chip being bonded to the chip seat of the lead frame with bonding agent, the gold lines being mounted at the predetermined electrically connection pin positions of the substrate and a pin pad so as to function as output, and heat energy evolved in the course of operation of the chip is dissipated from the chip seat via the support belt to other regions of the lead frame for dissipation.

In the present invention, the lead frame 1 is bonded to the substrate 3, then the chip 2 is mounted onto the chip seat 11 of the lead frame 1, and a plurality of gold lines 22 are used to connect the chip pin pad 21 and the substrate 3. Finally, a sealing gel 4 is used to fill the groove 13 and covers the gold lines 22 and a partial of the surface area of the lead frame 1.

In accordance with the present invention, the entire packaging body does not require copper plate or dissipation plate but possesses high numbers of pins. The lead frame can transfer the heat energy produced in the course of chip operation.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A high heat dissipation micro-packaging body for semiconductor chip comprising:
(a) lead frame having an etched recessed platform for a chip seat, the surrounding area of the platform being groove having a plurality of supporting belt connected to the lead frame;
(b) a substrate having a plurality of pins, corresponding to the position of the groove, for connection with gold lines;
(c) a chip being bonded to the chip seat of the lead frame with bonding agent, the gold lines being mounted at the predetermined electrically connection pin positions of the substrate and a pin pad so as to function as output, and heat energy evolved in the course of operation of the chip is dissipated from the chip seat via the support belt to other regions of the lead frame for dissipation.
